(19) United States
(12) Patent Application Publication
(10) Pub. No.: US 2013/0192435 A1
(43) Pub. Date: Aug. 1, 2013

(54) WAFER CUTTING METHOD AND DEVICE

(71) Applicant: STMicroelectronics (Tours) SAS, Tours (FR)

(72) Inventors: Vincent Jarry, La Membrolle sur Choisille (FR); Philippe Prunet, Neuvy le Roi (FR); Thierry Feuillette, La Membrolle sur Choisille (FR)

(73) Assignee: STMICROELECTRONICS (TOURS) SAS, Tours (FR)

(21) Appl. No.: 13/754,660

(22) Filed: Jan. 30, 2013

(30) Foreign Application Priority Data
Jan. 31, 2012 (FR) 1250890

(51) Int. Cl. H01L 21/463; B28D 5/04

(52) U.S. Cl. CPC H01L 21/463; B28D 5/042
USPC 83/19; 83/176

(57) ABSTRACT

A device for cutting a wafer provided with grooves on its upper surface having its lower surface supported by a flexible film secured to a frame. This device includes a system for locating the grooves and for positioning the frame with respect to a cutting system, and setting means for positioning the wafer in front of the locating system so that the located area is at a determined distance from the locating system.

### BACKGROUND

1. Technical Field

The present invention relates to a wafer cutting device, and more specifically to a device for cutting a semiconductor wafer into chips.

2. Description of the Related Art

FIG. 1 is a cross-section perspective view of a cutting system currently used to cut semiconductor wafers. A wafer 1 provided with grooves 3 on its upper surface is laid on a flexible film 5 secured to a frame 6. Flexible film 5 currently is an adhesive film bonded by its upper surface to wafer 1 and to frame 6.

On the lower surface side of the wafer, a cutting blade 8 is arranged in front of a U-shaped hammer 9 having a length corresponding to the wafer diameter.

Cutting blade 8 should be arranged in front of a groove 3 and U-shaped hammer 9 is to be placed astride the external edges of the two chip lines adjacent to a groove. The cutting is currently performed by pressing U-shaped hammer 9 towards cutting blade 8. Cuttings in one direction are then performed, followed by cuttings in a perpendicular direction.

A problem which arises while performing such cuttings is how to very accurately position the U-shaped hammer and cutting blade assembly at the proper location with respect to a groove 3. For this purpose, locating devices such as a video camera 11 taking a view of orthogonal grooves and aligning it on a target located with respect to the cutting blade and U-shaped hammer assembly are generally provided. A fine translation and rotation of the frame with respect to the cutting blade and U-shaped hammer assembly is then performed to achieve a desired positioning.

FIG. 2A, 2B, and 2C are successive cross-section views of cutting steps. These drawings are at a scale showing more detail than FIG. 1.

It is assumed in the drawings that cutting blade 8 and U-shaped hammer 9 have been properly positioned with respect to a groove 3i of wafer 1 laid on flexible film 5. Further, the case where the wafer is a silicon wafer having its rear surface (the upper surface in the representation of FIG. 2A to 2C) provided with connection bumps 20 has been illustrated. Further, a thin flexible film 22, for example made of Mylar, is laid on the upper surface of the structure to avoid damaging the chips when the U-shaped hammer presses against the wafer.

Thus, FIG. 2A shows a first step where U-shaped hammer 9 is not engaged yet, FIG. 2B shows a step where the U-shaped hammer starts engaging and presses on flexible film 22, and FIG. 2C shows a step of wafer breakage while the U-shaped hammer has been driven. In these drawings, vertical lines 24 indicate that cuttings have already been performed to the right of the groove concerned by the ongoing cutting.

The representation of FIG. 1 shows a general system where locating device 11 is placed at the same level as the assembly of U-shaped hammer 9 and of cutting blade 8.

In practice, a system in which the actual cutting unit and the groove locating unit are separated may be provided, the frame being laterally displaced from one unit to the other. This is illustrated in the representation of FIG. 3A and 3B. In a first position of the wafer, illustrated in FIG. 3A, frame 6 and cutting blade 8 are arranged so that groove 3i of wafer 1 at the level of which the cutting is desired to be performed faces locating device 11. A system, not shown, of fine lateral and angular adjustment of the frame is also provided so that the cutting blade is properly aligned with groove 3i. FIG. 3B illustrates a second position of the frame in which the assembly of frame 6 and of cutting blade 8 is displaced so that groove 3i where the cutting is desired to be performed and the cutting blade are located in front of U-shaped hammer 9, said displacement being able to be performed with great accuracy.

It should be noted that, to make the drawings more easily readable, the cutting blade and the U-shaped hammer have been shown to extend perpendicularly to the displacement direction. It will often in practice be preferred for the cutting blade and the U-shaped hammer to be arranged parallel to the displacement direction.

The previously-described locating, positioning, and cutting system is satisfactory in most cases. However, currently-used locating devices are extremely sensitive to misfocusings. Thus, when a wafer is curved, and even slightly so, it becomes necessary to reset the locating device according to the observed wafer location. Such a setting step results in a significant loss of time for operators in charge of the system, and thus in a significant increase of the total wafer processing time.

### BRIEF SUMMARY

An embodiment provides a method for cutting a wafer provided with grooves on its upper surface and having its lower surface supported by a flexible film assembled on a frame, using a system for locating the grooves and for positioning the frame with respect to a cutting system, comprising, during the locating step, the step of positioning the wafer perpendicularly to its main plane to impose for the located area to be at a determined distance from the locating system.

According to an embodiment, the cutting system comprises a cutting blade on the lower surface side and a U-shaped hammer on the upper surface side.

According to an embodiment, the wafer cutting system further comprises, during the locating step, the step of maintaining the upper surface of the wafer in the vicinity of the located area, by a flexible bearing element.

Another embodiment provides a device for cutting a wafer, provided with grooves on its upper surface and having its lower surface supported by a flexible film secured to a frame, comprising a system for locating the grooves and for positioning the frame with respect to a cutting system; and setting means for positioning the wafer in front of the locating system so that the located area is at a determined distance from the locating system.

According to an embodiment, the setting means are a bearing element perpendicularly mobile with respect to the wafer plane.

According to an embodiment, the cutting device comprises a cutting blade on the lower surface side and a U-shaped hammer on the upper surface side.

According to an embodiment, the device for cutting a wafer comprises an additional flexible bearing element on the upper surface side of the wafer in front of said bearing element.

According to an embodiment, the wafer is a semiconductor wafer having its upper surface comprising connection bumps.

According to an embodiment, the cutting device comprises a flexible film arranged on the upper surface of the wafer.

According to an embodiment, the cutting device comprises means for displacing the wafer between a locating unit where the bearing element is actuated and a cutting unit where the bearing element is withdrawn.

### BRIEF DESCRIPTION OF THE DRAWINGS

The foregoing and other features and advantages will be discussed in detail in the following non-limiting description of specific embodiments in connection with the accompanying drawings.

FIG. 1, previously described, is a perspective cross-section view of a semiconductor wafer cutting system;

FIG. 2A, 2B, and 2C, previously described, are cross-section views illustrating successive steps of the cutting of a semiconductor wafer;

FIG. 3A and 3B, previously described, are perspective cross-section views illustrating two successive steps of a system for locating, positioning, and cutting a semiconductor wafer;

FIG. 4 is a cross-section view illustrating a curved wafer assembled on a flexible film secured to a frame;

FIG. 5A and 5B illustrate successive wafer locating and cutting steps; and

FIG. 6 shows a variation of a wafer locating and cutting system.

### DETAILED DESCRIPTION

For clarity, the same elements have been designated with the same reference numerals in the different drawings and, further, as usual in the representation of semiconductor components, the various drawings are not to scale.

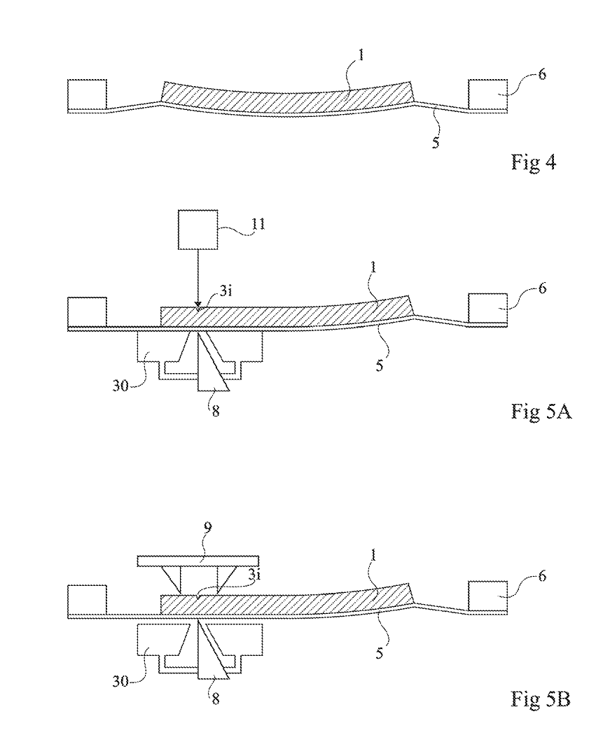

FIG. 4 is a cross-section view showing in exaggerated fashion what happens when a wafer is non-planar. This is hardly visible to the naked eye but results from the fact that silicon wafers, especially when they are provided with bumps, have been thinned, and have undergone various thermal steps, tend to slightly curve. This drawing illustrates a wafer 1 bonded to a flexible film 5 assembled on the lower surface of a frame 6.

When such curved wafers are desired to be cut, failures of the automatic wafer positioning system for aligning a groove on a cutting system can be observed.

Such failures are essentially imputed to the fact that the setting of the locating device on the wafer becomes poor since the distance between the wafer surface and the locating device is variable. Other defects seem to be due to the fact that the previously-described upper flexible film (the Mylar film) is oblique and not orthogonal to the observation direction and that this tends to introduce parasitic light into the locating device.

One or more embodiments of the systems described herein may overcome these disadvantages without having to successively set the observation system according to the location of the observed wafer. Indeed, such successive setting steps result in a significant loss of time for operators in charge of the system, and thus in a significant increase of the total wafer processing time.

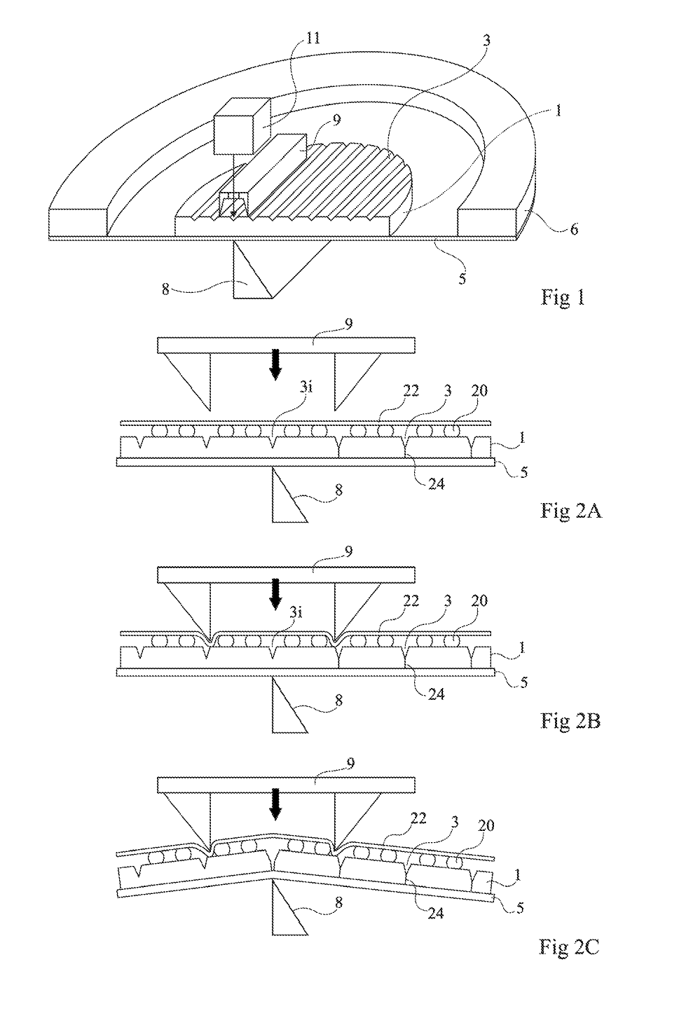

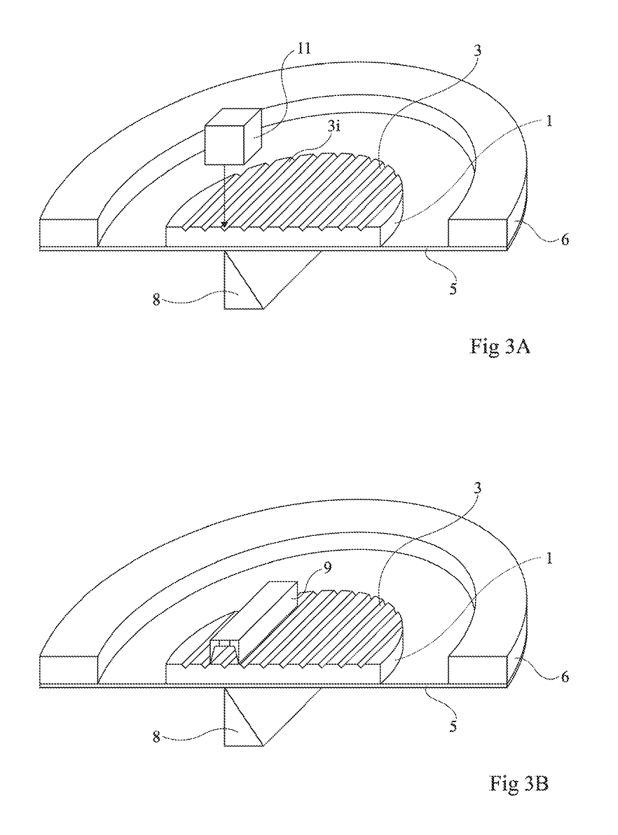

FIG. 5A shows the cutting installation during the locating step. Curved wafer 1 is laid on film 5 and maintained by frame 6. Opposite to wafer locating device 11, under wafer 1, is arranged cutting blade 8. This cutting blade is surrounded with a bearing element or mobile anvil 30. In that regard, the anvil 30 may extend across a substantial portion or the entire length of the wafer 1. As is best shown in FIGS. 5A and 5B, the anvil 30 includes planar surfaces that surround at least two sides of the cutting blade 8. This anvil is raised during the locating phase, in the position shown in FIG. 5A, so that, at the level of the locating device observation area, the wafer is in the plane where it would have been, had it been planar. The locating can then be accurately performed. A fine angular and lateral setting of the frame with respect to the cutting blade is then performed by a device, not shown, so that the cutting blade is aligned on groove 3i where the cutting is desired to be performed. After this, as shown in FIG. 5B, bearing device or anvil 30 is lowered and cutting blade 8 is in a position such that it faces U-shaped hammer 9. The offset between the position of FIG. 5A and that of FIG. 5B is performed accurately so that the device faces the U-shaped hammer. The cutting is then carried out conventionally, for example, as described in relation with FIG. 2A to 2C.

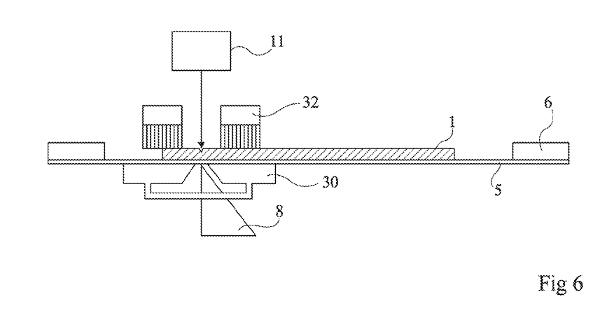

FIG. 6 shows a variation of the structure of FIG. 5A. It shows the same elements designated with the same reference numerals. Further, a flexible bearing structure 32, for example, a brush intended to better ensure the planeness of wafer 1 at the level of the observation area, is provided on the upper surface side.

As indicated previously, in the case of FIG. 5A, 5B, and 6, the cutting blade and the U-shaped hammer are preferably arranged perpendicularly to the direction indicated in the drawing, and not in that direction.

Several successive cuttings may be performed without returning to the observation unit. It is however desirable to regularly return to the observation unit to reset the cutting system, for example, every three to ten grooves, according to the desired number of cuttings, that is, according to the dimension of the elementary chips which are desired to be cut in the wafer.

A specific locating, positioning, and cutting system has been described and schematically shown hereabove. Various systems may be used. Generally described, the cutting device is to be accurately located by means of a device accurately setting the distance between the observed area of the wafer and the locating device, during the locating phase. The means for setting the “height” of the observed area have been described as a bearing element of settable height. Any other means performing this function may be used, for example, a depression system. Similarly, the locating device may be one of many known devices, for example, using an optical camera.

Further, the wafer may be, as described in relation with prior art, a semiconductor wafer having its rear surface, which is its upper surface in the drawings, provided with connection bumps. The present invention applies not only to silicon wafers, but also to various types of semiconductor or non-semiconductor wafers, for example, wafers made of SiC, sapphire, glass, etc. Further, in the system described in relation with FIG. 5A, 5B, and 6, in the same way as in the case of the system described in relation with FIG. 2A to 2C, a flexible film will preferably be provided on the upper surface side of the wafer, to avoid its damaging by the cutting device during the cutting.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A method for cutting a wafer, comprising:
making at least a portion of the wafer more planar by pressing a bearing element against a second surface of the wafer, the portion of the wafer being proximate a first groove on a first surface of the wafer;
aligning the wafer with a cutting blade so that the cutting blade is located proximate the second surface of the wafer that is opposite the first groove; and
cutting the wafer along the first groove.

2. The method of claim 1, wherein cutting the wafer along the first groove comprises pressing a cutting blade on the second surface opposite the first groove and pressing a U-shaped member on the first surface outwardly of the first groove.

3. The method of claim 1, wherein the bearing element is flexible.

4. The method of claim 1, further comprising pressing a brush against the first surface of the wafer.

5. The method of claim 1, wherein making at least the portion of the wafer more planar by pressing a bearing element against the second surface of the wafer comprises causing the portion of the first surface of the wafer to be a particular distance from a locating system configured to align the wafer with the cutting blade.

6. The method of claim 1, wherein aligning the wafer with the cutting blade comprises moving the wafer relative to the cutting blade.

7. A device for cutting a wafer, comprising:
a cutting system;
a locating system configured to locate grooves on an upper surface of the wafer and position the wafer with respect to the cutting system; and
means for making at least a portion of the wafer more planar.

8. The wafer cutting device of claim 7, wherein the means includes a bearing element configured to press against at least a portion of a lower surface of the wafer.

9. The wafer cutting device of claim 8, wherein the means further includes a flexible bearing element configured to press against the upper surface of the wafer.

10. The wafer cutting device of claim 8, wherein the bearing element is configured press against at least the portion of the lower surface of the wafer to cause at least a portion of the upper surface of the wafer to be a determined distance from the locating system.

11. The wafer cutting device of claim 9, wherein the cutting system comprises a cutting blade located proximate the lower surface of the wafer and a U-shaped hammer proximate the upper surface of the wafer.

12. The wafer cutting device of claim 9, comprising means for displacing the wafer between the locating system where the bearing element is actuated and the cutting system where the bearing element is withdrawn.

13. A wafer cutting device, comprising:
a cutting system having a blade configured to cut a wafer along a groove located on an upper surface of the wafer;
a locating system configured to locate the groove on the upper surface of the wafer and position the groove with respect to the blade of the cutting system; and
a bearing element configured to press against a lower surface of the wafer proximate the groove causing at least a portion of the wafer to be more planar.

14. The wafer cutting device of claim 13, wherein the bearing element causes at least the portion of the upper surface of the wafer to be a particular distance from the locating system.

15. The wafer cutting device of claim 14, wherein the bearing element is moveable with respect to the wafer and is located proximate a lower surface of the wafer.

16. The wafer cutting device of claim 14, further comprising a flexible bearing element configured to press against the upper surface of the wafer.

17. The wafer cutting device of claim 16, wherein the flexible bearing element is a brush.

18. The wafer cutting device of claim 14, wherein the cutting system includes a U-shaped member proximate the upper surface of the wafer.

19. The wafer cutting device of claim 18, wherein the lower surface of the wafer opposite the groove is positioned proximate the blade.
